(19) United States
(12) Patent Application Publication
(10) Pub. No.: US 2008/0079468 A1
(43) Pub. Date: Apr. 3, 2008

(54) LAYOUT METHOD FOR SEMICONDUCTOR INTEGRATED CIRCUIT

(75) Inventor: Masahiro SUGINAKA, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/861,535

(22) Filed: Sep. 26, 2007

(30) Foreign Application Priority Data
Sep. 29, 2006 (JP) 2006-267668

(51) Int. Cl. H03L 7/00; G06F 17/50

(52) U.S. Cl. 327/153; 716/9

(57) ABSTRACT

A layout method for a semiconductor integrated circuit according to the present invention is a layout method for a semiconductor integrated circuit including plural delay adjustment cells each of which adjusts a delay amount of a signal line. The layout method includes: placing the plural delay adjustment cells; adjusting delay amounts of the plural delay adjustment cells placed in the placing; extracting delay adjustment cells of a same kind from among the plural delay adjustment cells having the delay amounts adjusted in the adjusting; and consolidating the delay adjustment cells of the same kind extracted in the extracting, to obtain a shared delay adjustment cell.

### BACKGROUND OF THE INVENTION

(1) Field of the Invention

The present invention relates to a layout method for a semiconductor integrated circuit, and particularly to a layout method for a semiconductor integrated circuit including plural delay adjustment cells each of which adjusts a delay amount of a signal line.

(2) Description of the Related Art

In layout design of a semiconductor integrated circuit, it is possible to reduce modifications of a layout after placement and routing and to adjust timing with a small number of man-hours by using delay adjustment cells of which delay time is variable.

The delay adjustment cells of which the delay time is variable are provided to plural clock domains configured by considering placement information, logical configuration and a clock tree (CTS) in a clock logic circuit respectively (refer to Patent Document 1 for instance).

Hereunder, a flow of conventional layout design for a semiconductor integrated circuit will be described.

FIG. 1 is a flowchart showing the flow of the conventional layout design for the semiconductor integrated circuit.

First, circuit design is performed, and functional description such as a hardware description language (HDL) or the like is performed (S1001). Next, the hardware description language or the like is logically synthesized, and a netlist of a logic circuit of a gate level is generated (S1002).

Next, the layout is created from the logic circuit of the gate level. First, basic cells including the delay adjustment cells are placed (S1003). Next, the clock tree (CTS) is formed and a clock line is placed. The delay adjustment cells are also inserted at predetermined locations of the clock line (S1004). Next, routing for connecting the basic cells and the like is placed (S1005). Next, a delay adjustment is made to the delay adjustment cells inserted into the clock line (S1006).

The formed layout undergoes operational verification by simulation and the like (S1007).

### [Patent Document 1] Japanese Unexamined Patent Application Publication No. 2003-273222

### SUMMARY OF THE INVENTION

However, a large-scale semiconductor integrated circuit requires a large number of delay adjustment cells for a delay adjustment. Therefore, according to a conventional layout method for a semiconductor integrated circuit, the number of the delay adjustment cells increases as a circuit size becomes larger. For this reason, there are problems that power consumption and area of the semiconductor integrated circuit increase.

Thus, an object of the present invention is to provide a layout method for a semiconductor integrated circuit which can reduce the power consumption and the area of the semiconductor integrated circuit.

In order to achieve the above object, the layout method for the semiconductor integrated circuit according to the present invention is a layout method for a semiconductor integrated circuit including plural delay adjustment cells each of which adjusts a delay amount of a signal line. The layout method includes: placing the plural delay adjustment cells; adjusting delay amounts of the plural delay adjustment cells placed in the placing; extracting delay adjustment cells of a same kind from among the plural delay adjustment cells having the delay amounts adjusted in the adjusting; and consolidating the delay adjustment cells of the same kind extracted in said extracting, to obtain a shared delay adjustment cell.

According to this, in the layout method for the semiconductor integrated circuit according to the present invention, the delay adjustment cells having circuits configured with the same kind of logic cells are extracted in the extracting, and the extracted delay adjustment cells are consolidated to obtain the shared delay adjustment cell in the consolidating. Thus, it is possible to reduce the delay adjustment cells by commonly using the shared delay adjustment cell. It is thereby possible to reduce the area (chip size) of the semiconductor integrated circuit. It is also possible to realize reduction in the power consumption by reducing the delay adjustment cells. Furthermore, the reduction in the power consumption allows suppression of low power supply voltage. To be more specific, the layout method for the semiconductor integrated circuit according to the present invention can reduce the power consumption and the area of the semiconductor integrated circuit. It is also possible to lower a packing rate of the semiconductor integrated circuit by the region generated by the reduction of the delay adjustment cells. There are newly possible measures, such as placing capacity cells which are effective in measures against noise and the low power supply voltage, and the like. Furthermore, variations in clocks that use the delay adjustment cells which have been consolidated can be suppressed by commonly using the shared delay adjustment cell having the same configuration.

It is also possible that the layout method for the semiconductor integrated circuit further includes re-placing the plural delay adjustment cells including the shared delay adjustment cell obtained in the consolidating, so as to reduce area of a region where the plural delay adjustment cells are placed.

According to this, in the re-placing, the shared delay adjustment cell is re-placed so as to reduce the area of the region where the delay adjustment cells are placed. It is thereby possible to reduce the area of the delay adjustment cells. It is also possible to reduce the area (chip size) of the semiconductor integrated circuit and realize efficient layout design by considering reduction in the area in advance and taking a precaution, such as adjacently placing the delay adjustment cells in a placement (floor plan) process step.

It is also possible that the re-placing includes aligning and re-placing the plural delay adjustment cells including the shared delay adjustment cell obtained in the consolidating in an order depending on a size of the area of the delay adjustment cells.

According to this, it is possible to expand the region generated by consolidating the delay adjustment cells and to realize further reduction in the area of the semiconductor integrated circuit. Moreover, a region where basic logic cells and the like generated by consolidating the delay adjustment cells can be placed is put in a regular shape. Efficient placement of the basic logic cells and the like are thereby allowed.

It is also possible that the placing includes placing an input-side logic cell and an output-side logic cell of the plural delay adjustment cells, so that the input-side logic cell and the output-side logic cell are respectively arranged on diagonally opposing sides of a region where the plural delay adjustment cells are placed.

According to this, in re-placement and re-routing by consolidating the delay adjustment cells in the consolidating and re-placing the delay adjustment cells in the re-placing, it is possible to suppress a change in overall routing length from the logic cell on the input-side to the logic cell on the output-side of each signaling system (such as a clock system). Therefore, it is possible to suppress fluctuation in a delay amount in conjunction with consolidating and re-placement of the delay adjustment cells.

It is also possible that the layout method for the semiconductor integrated circuit further includes predicting the delay adjustment cells of the same kind from among the plural delay adjustment cells and that the placing includes adjacently placing the delay adjustment cells of the same kind predicted in the predicting.

According to this, in the predicting, the configuration of the delay adjustment cells after the delay adjustment is predicted from a circuit configuration, placement information and the like of the signal line of each clock system and the like. In the adjusting, the delay adjustment cells presumed to have the same configuration are placed adjacently in advance. It is thereby possible to reduce an amount of modification of placement and routing in the consolidating and the re-placement of the delay adjustment cells. Therefore, it is possible to suppress delay fluctuation of the signal line of the clock system or the like in conjunction with the consolidating and the re-placement of the delay adjustment cells.

It is also possible that the consolidating includes consolidating the delay adjustment cells of the same kind extracted in the extracting, to obtain one shared delay adjustment cell for every predetermined number or less of the delay adjustment cells.

According to this, in consolidating the delay adjustment cells, there is a limit to the number of the delay adjustment cells of the same configuration to be consolidated. It is thereby possible to limit the number of outputs (fan-outs) of output cells in a final stage of the delay adjustment cells which become a cause of a delay and suppress the delay fluctuation in conjunction with consolidating the delay adjustment cells.

It is also possible that the layout method for the semiconductor integrated circuit further includes: dividing a region where the plural delay adjustment cells are placed in the placing into plural re-placement target regions; the extracting includes extracting the delay adjustment cells of the same kind from among the plural delay adjustment cells included in each of the re-placement target regions; and the consolidating includes consolidating the delay adjustment cells of the same kind extracted in the extracting to obtain the shared delay adjustment cell, for each of the re-placement target regions.

According to this, the region of the layout where the delay adjustment cells are placed is divided into plural re-placement target regions, and the delay adjustment cells are consolidated and re-placed for every divided re-placement target region. It is thereby possible to suppress extension of the routing after the re-placement and reduce influence of the delay fluctuation.

The semiconductor integrated circuit according to the present invention includes: plural delay adjustment cells having an input connected to a clock terminal and which impart a predetermined delay to an inputted signal and output the signal; plural selectors each of which selects one of the signal outputted by the plural delay adjustment cells and a signal from a test terminal, and outputs the signal; and plural flip-flops each of which has a clock input terminal to which the signal outputted by one of the plural selectors is inputted.

According to the configuration, in the semiconductor integrated circuit according to the present invention, the delay adjustment cells are consolidated to be shared by plural selectors. It is thereby possible to reduce the number of the delay adjustment cells. Thus, it is possible to reduce the area (chip size) of the semiconductor integrated circuit. It is also possible to realize reduction in the power consumption by reducing the delay adjustment cells. Furthermore, the reduction in the power consumption allows the suppression of low power supply voltage. It is also possible to lower a packing rate of the semiconductor integrated circuit by the region generated by the reduction of the delay adjustment cells. There are newly possible measures, such as placing capacity cells which are effective in measures against the noise and the low power supply voltage, and the like. Furthermore, variations in clocks that use the delay adjustment cells which have been consolidated can be suppressed by commonly using the shared delay adjustment cell.

Moreover, the present invention can be realized not only as the layout method for the semiconductor integrated circuit and the semiconductor integrated circuit as described but also as a program which causes a computer to execute characteristic steps included in the layout method for the semiconductor integrated circuit. And it goes without saying that such a program can be distributed via a recording medium such as a CD-ROM and a transmission medium such as the Internet.

The present invention can provide the layout method for the semiconductor integrated circuit which reduces the power consumption and the area of the semiconductor integrated circuit.

### Further Information about Technical Background to this Application

The disclosure of Japanese Patent Application No. 2006-267668 filed on Sep. 29, 2006 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention.

In the drawings:

FIG. 1 is a flowchart showing a flow of a conventional layout method;

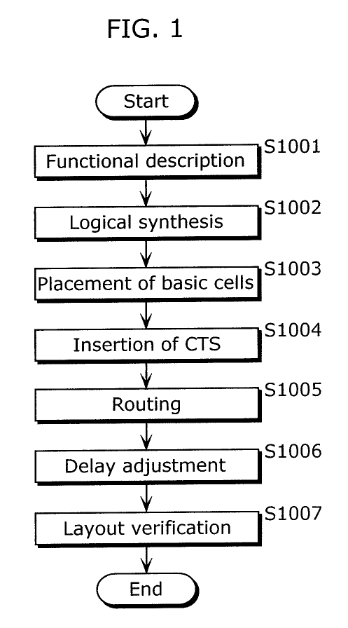

FIG. 2 is a flowchart showing a flow of processing a layout method according to a first embodiment of the present invention;

FIG. 3 is a circuit diagram showing an example of a circuit configuration of a clock system;

FIG. 4 is a circuit diagram showing a circuit configuration after consolidating delay adjustment cells in the layout method according to the first embodiment of the present invention;

FIG. 5 is a diagram showing an example of a layout before consolidating the delay adjustment cells;

FIG. 6 is a diagram showing a layout after consolidating the delay adjustment cells in the layout method according to the first embodiment of the present invention;

FIG. 7 is a diagram showing a layout after re-placing the delay adjustment cells in the layout method according to the first embodiment of the present invention;

FIG. 8 is a diagram showing a layout after consolidating the delay adjustment cells in the layout method according to the first embodiment of the present invention;

FIG. 9 is a diagram showing a layout after consolidating the delay adjustment cells in the layout method according to a second embodiment of the present invention;

FIG. 10 is a diagram showing an example of a layout before consolidating the delay adjustment cells in the layout method according to a third embodiment of the present invention;

FIG. 11 is a diagram showing a layout after consolidating the delay adjustment cells in the layout method according to the third embodiment of the present invention;

FIG. 12 is a flowchart showing a flow of processing the layout method according to a fourth embodiment of the present invention;

FIG. 13 is a diagram showing an example of a layout before consolidating the delay adjustment cells;

FIG. 14 is a diagram showing a layout after consolidating the delay adjustment cells in the layout method according to a fifth embodiment of the present invention;

FIG. 15 is a diagram showing a layout before consolidating the delay adjustment cells in the layout method according to a sixth embodiment of the present invention; and

FIG. 16 is a diagram showing a layout after consolidating the delay adjustment cells of the layout shown in FIG. 15 in the layout method according to the sixth embodiment of the present invention.

### DESCRIPTION OF THE PREFERRED EMBODIMENTS

A layout method for a semiconductor integrated circuit according to embodiments of the present invention will be described hereinafter with reference to the drawings.

A layout method for a semiconductor integrated circuit according to a first embodiment of the present invention is a layout method for a semiconductor integrated circuit including plural delay adjustment cells each of which adjusts a delay amount of a signal line. In the layout method, the delay adjustment cells of the same configuration are consolidated to obtain a shared delay adjustment cell after a delay adjustment so that the delay adjustment cells are compressed. It is thereby possible to reduce power consumption and circuit area of the semiconductor integrated circuit.

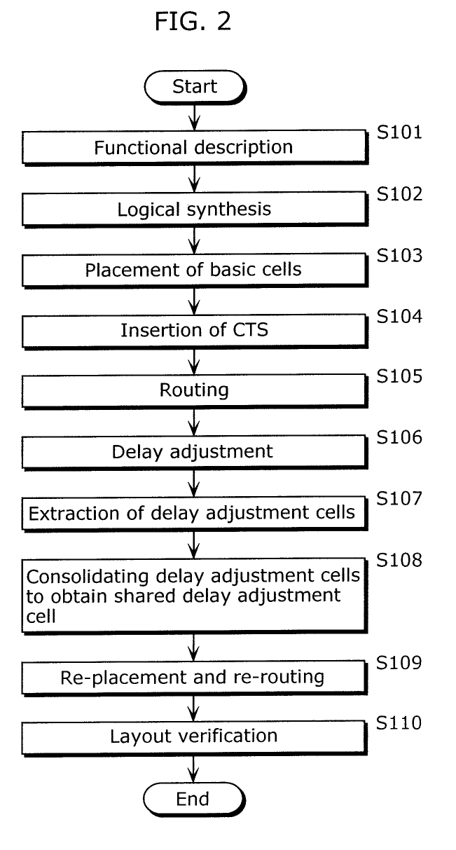

FIG. 2 is a flowchart showing a flow of the layout method for the semiconductor integrated circuit according to the first embodiment of the present invention.

First, circuit design is performed, and functional description such as a hardware description language (HDL) or the like is performed (S101). Next, the hardware description language or the like is logically synthesized, and a netlist of a gate-level logic circuit is generated (S102).

Next, the layout is created from the gate-level logic circuit. First, basic cells including the delay adjustment cells are placed (S103). Next, the clock tree (CTS) is formed and a clock line is placed. The delay adjustment cells are inserted at predetermined locations of the clock line (S104). Next, routing for connecting the basic cells and the like is placed (S105). Next, an adjustment is made to the delay amounts of the delay adjustment cells inserted into the clock line (S106).

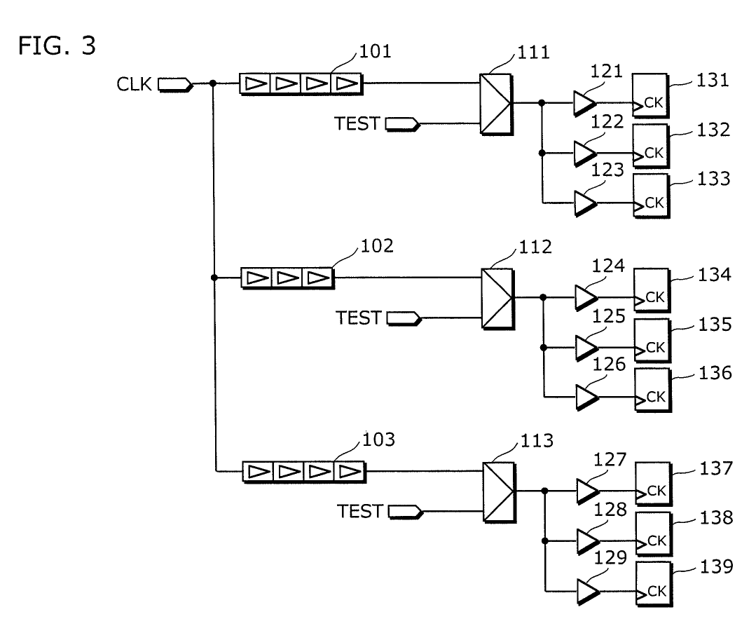

FIG. 3 is a circuit diagram showing an example of logic circuits of a clock system formed by the process up to the step S106.

The logic circuits shown in FIG. 3 include delay adjustment cells 101 to 103, selectors 111 to 113, buffers 121 to 129 and flip-flops 131 to 139.

The delay adjustment cells 101 to 103 are circuits for giving a predetermined delay to an input signal and outputting it, and their inputs are connected to a clock terminal CLK. For instance, the delay adjustment cells 101 and 103 give a delay of 4 ns to the input signal and output signals, and the delay adjustment cell 102 gives a delay of 3 ns to the input signal and outputs them.

Each of the selectors 111 to 113 selects one of the delay adjustment cells 101 to 103 and a test terminal TEST and outputs it. The signals outputted by the selector 111 are inputted to clock input terminals of the flip-flops 131 to 133 via the buffers 121 to 123 respectively. The signals outputted by the selector 112 are inputted to clock input terminals of the flip-flops 134 to 136 via the buffers 124 to 126 respectively. The signals outputted by the selector 113 are inputted to clock input terminals of the flip-flops 137 to 139 via the buffers 127 to 129 respectively.

Next, in the layout method for the semiconductor integrated circuit according to the present embodiment, the delay adjustment cells of a circuit configuration having the same kind of logic cells are extracted from among the plural delay adjustment cells of which delay amounts have been adjusted in the step S106 (S107).

In the step S107, for example, the delay adjustment cells 101 and 103 of the circuit configuration having the same logic cells are extracted from among the delay adjustment cells 101 to 103 in a clock domain configured as in FIG. 3.

Next, in the step S107, the extracted delay adjustment cells of the same kind are consolidated to obtain the shared delay adjustment cell (S108).

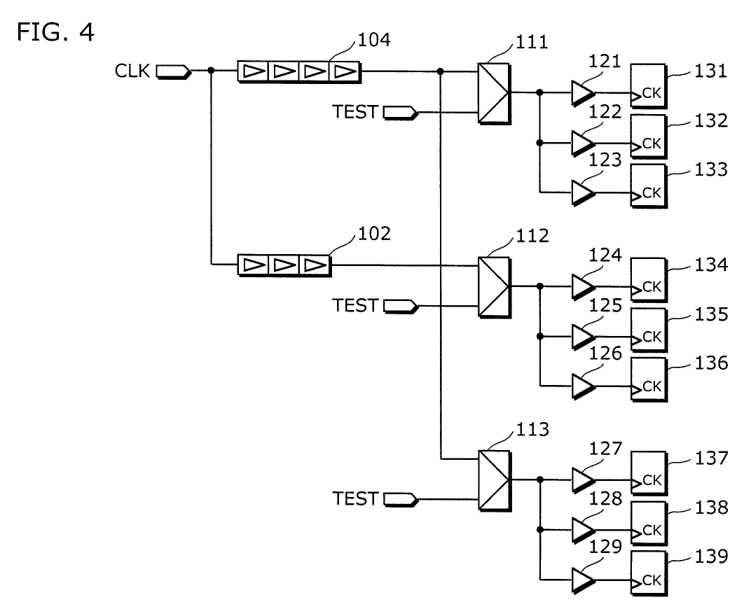

FIG. 4 is a circuit diagram of a logic circuit after consolidating the delay adjustment cells on the logic circuit shown in FIG. 3 (S108). The same elements as in FIG. 3 are given the same symbols, and a detailed description thereof is omitted.

In the step S108, for example, the extracted delay adjustment cells 101 and 103 are consolidated to obtain the shared delay adjustment cell as shown in FIG. 4, and the delay adjustment cell 104 is placed instead of the delay adjustment cells 101 and 103. Here, the delay adjustment cell 104 is the circuit configuration having the same kind of logic cells that generate the same delay as the delay adjustment cells 101 and 103. As shown in FIG. 4, routing connections are changed so as to have the same function as the logic circuit shown in FIG. 3.

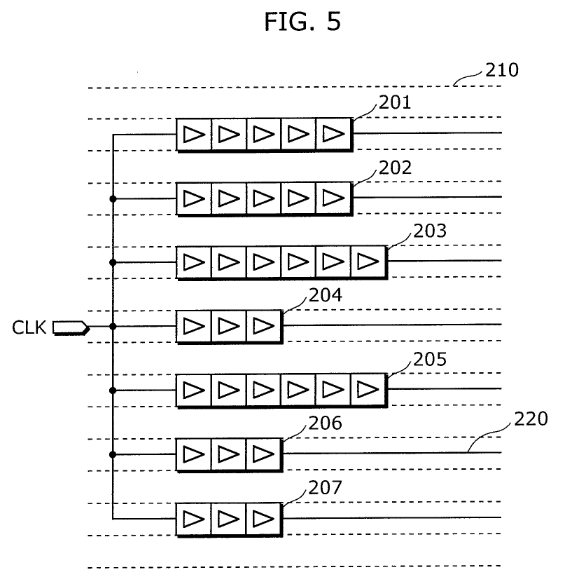

FIG. 5 is a diagram showing an example of a layout of the delay adjustment cells placed in the process up to the step S106. In FIG. 5, the layout of seven delay adjustment cells is used in order to clarify the description, which is not consistent with the logic circuits of FIGS. 3 and 4.

The layout shown in FIG. 5 includes delay adjustment cells 201 to 207. A broken line 210 in FIG. 5 indicates a placement row which is a layout unit of the delay adjustment cells.

The delay adjustment cells 201 and 202 are both the circuit configurations having the same kind of logic cells that generate the same delay, and generate a delay of 5 ns for instance. The delay adjustment cells 203 and 205 are both the circuit configurations having the same kind of logic cells that generate the same delay, and generate a delay of 6 ns for instance. The delay adjustment cells 204, 206 and 207 are all the circuit configurations having the same kind of logic cells that generate the same delay, and generate a delay of 3 ns for instance. The delay adjustment cells 201 to 207 are placed so that inputs are in the same direction (left side in FIG. 5).

After the step S108, re-placement and re-routing of the layout of the delay adjustment cells are performed (S109).

In the re-placement and re-routing of the layout (S109), the delay adjustment cells of the layout are consolidated to obtain the shared delay adjustment cell first. Consolidating the layout can be performed by using information on the logic circuit consolidated in the step S108.

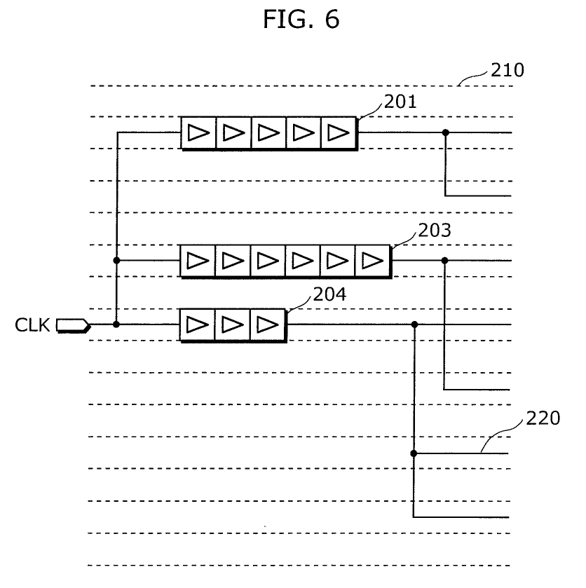

FIG. 6 is a diagram showing a layout after consolidating the delay adjustment cells has been performed to the layout shown in FIG. 5. In FIG. 6, the same elements as in FIG. 5 are given the same symbols.

As shown in FIG. 6, unnecessary delay adjustment cells are deleted by using the information on the logic circuit formed in the step S107. For instance, the delay adjustment cells 202, 205, 206 and 207 are deleted. Connection of routing 220 is changed so as to be the same as the logic circuit formed in the step S107. In the layout after deleting the delay adjustment cells as shown in FIG. 6, the delay adjustment cells are placed at a great distance from one another among placement rows.

Next, the plural delay adjustment cells 201, 203 and 204 including the shared delay adjustment cells are re-placed so as to reduce the area where the plural delay adjustment cells 201, 203 and 204 are placed.

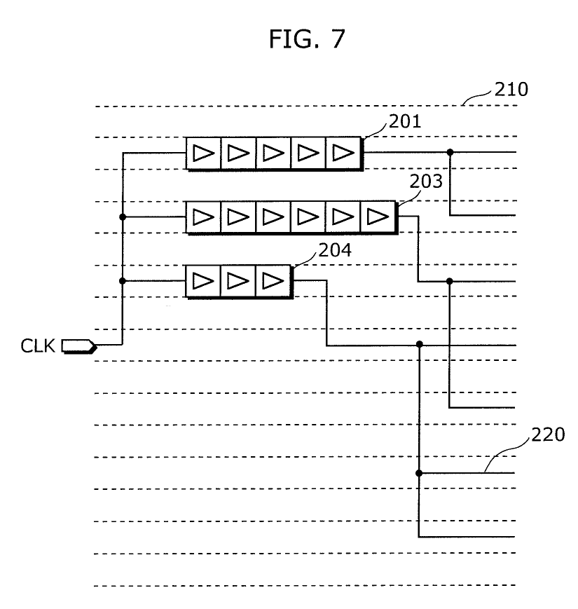

FIG. 7 is a diagram showing a layout after re-placing has been performed to the layout shown in FIG. 6. In FIG. 7, the same elements as in FIG. 6 are given the same symbols. As shown in FIG. 7, the delay adjustment cells 201, 203 and 204 are placed adjacently as a result of re-placement on the layout of the delay adjustment cells 201, 203 and 204. Note that, in FIGS. 5 to 7, the delay adjustment cells are placed in every other row. However, an adjacent placement in every row or the like can be arbitrarily determined. The layout of the semiconductor integrated circuit is formed as described above.

Operational verification is performed to the formed layout by simulation or the like (S110).

As described above, in the layout method for the semiconductor integrated circuit according to the first embodiment of the present invention, the delay adjustment cells having circuits configured with the same kind of logic cells of the same delay amount are consolidated to obtain the shared delay adjustment cell in the step S108, and the layout in which the delay adjustment cells are consolidated is created in the step S109. The delay adjustment cells are thereby reduced. Thus, it is possible, in a placement (floor plan) process step, to consider a floor plan in which the reduced area amount in the step S108 is taken into account in advance so that the area (chip size) of the semiconductor integrated circuit can be consequently reduced. It is also possible to reduce the power consumption by reducing the delay adjustment cells. Furthermore, the reduction in the power consumption allows suppression of low power supply voltage. It is also possible to lower a packing rate of the semiconductor integrated circuit by the region generated by the reduction of the delay adjustment cells. Moreover, there are newly possible measures, such as placing capacity cells which are effective in measures against noise and the low power supply voltage, and the like.

Furthermore, according to the layout method for the semiconductor integrated circuit of the present embodiment, it is possible that variations in clocks can be suppressed by commonly using the shared delay adjustment cell having the same configuration.

Furthermore, according to the layout method for the semiconductor integrated circuit of the present embodiment, the layout of the shared delay adjustment cell is re-placed in order to align the delay adjustment cells in the step S109. It is thereby possible to effectively utilize the region generated by consolidating the delay adjustment cells to obtain the shared delay adjustment cell.

In a layout method for a semiconductor integrated circuit according to a second embodiment, re-placement is performed by considering the circuit area in the step S109 in addition to the layout method of the first embodiment.

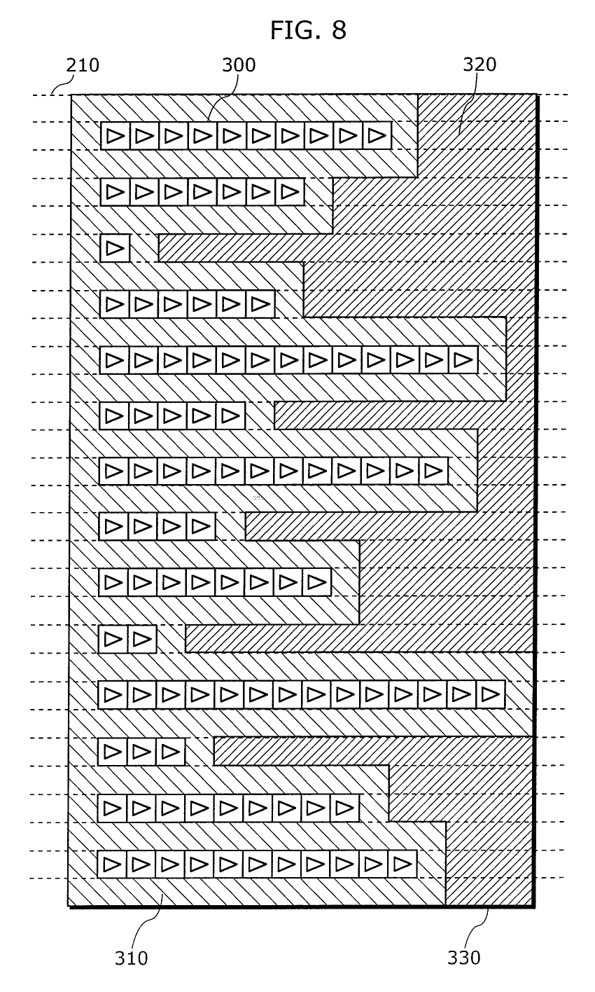

FIG. 8 is a diagram showing an example of a layout after performing the above-mentioned layout re-placement in the step S109. As in the first embodiment, FIG. 8 is the layout in the case of simply aligning the delay adjustment cells with respect to the region generated in conjunction with deletion of the delay adjustment cells.

The layout shown in FIG. 8 includes plural delay adjustment cells 300 each of which has different delay amounts, a capacity cell region 310 and a basic logic cell region 320.

The capacity cell region 310 is a region where capacity cells are placed. As for delay adjustment cells 300, it is necessary to prevent influence of noise and low power supply voltage because of their characteristic problem that clock signals are inputted and outputted. The capacity cells formed in the capacity cell region 310 are formed in order to prevent the influence of the noise and the low power supply voltage on the delay adjustment cells 300.

The basic logic cell region 320 is a region where the basic logic cells can be placed.

A comparison reference frame 330 shown in FIG. 8 is a frame to be used for comparison with the case of performing the re-placement of the second embodiment described later. The comparison reference frame 330 is a frame enclosing the region made up of a region where the delay adjustment cells 300 are placed, the capacity cell region 310 and the basic logic cell region 320. A broken line 210 in FIG. 8 indicates a placement row which is a layout unit of the delay adjustment cells.

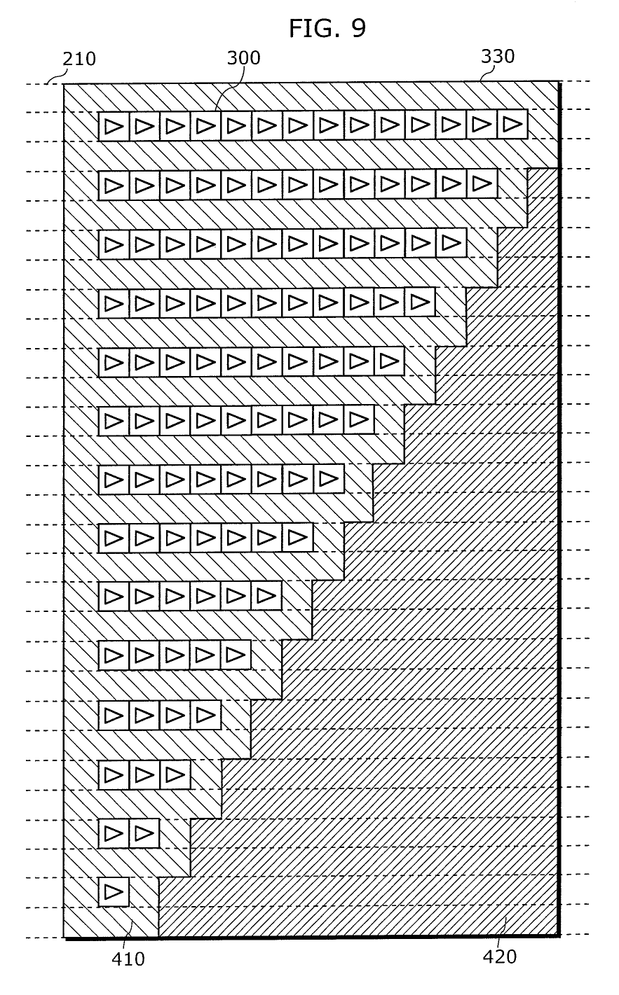

FIG. 9 is a diagram showing an example of a layout after performing the re-placement in the step S109 by the layout method for the semiconductor integrated circuit according to the second embodiment. The same elements as in FIG. 8 are given the same symbols, and a detailed description thereof is omitted.

The layout shown in FIG. 9 includes the plural delay adjustment cells 300 as with FIG. 8. Furthermore, the layout shown in FIG. 9 includes a capacity cell region 410 where the capacity cells are placed and a basic logic cell region 420 where the basic logic cells can be placed.

The layout shown in FIG. 9 is formed so that the region where the capacity cells placed in the capacity cell region 410 can be commonly used increases with respect to the delay adjustment cells 300 placed adjacently in a vertical direction. To be more specific, the capacity cell region 410 shown in FIG. 9 is a small region in comparison with the capacity cell region 310 shown in FIG. 8. For instance, the plural delay adjustment cells 300 including a shared delay adjustment cell obtained by consolidating delay adjustment cells are aligned in an order depending on a size of the area of the delay adjustment cells and are re-placed. To be more specific, as shown in FIG. 9, the delay adjustment cells 300 are sequentially placed in the vertical direction in an order from the one having the largest lateral length (largest delay amount). It is thereby possible to reduce the area of the capacity cell region 410. The area of the basic logic cell region 420 in the comparison reference frame 330 shown in FIG. 9 is larger than the area of the basic logic cell region 320 shown in FIG. 8. To be more specific, it is possible to realize an efficient placement of the delay adjustment cells 300.

As shown in FIG. 9, the basic logic cell region 420 is in a regular shape in comparison with the basic logic cell region 320 shown in FIG. 8. It is thereby possible to efficiently place the basic logic cells and the like in the basic logic cell region 420.

As described above, according to the layout method for the semiconductor integrated circuit according to the second embodiment of the present invention, the re-placement is performed in the step S109, where the delay adjustment cells 300 are aligned so that the region where the capacity cells placed in the capacity cell region 410 can be commonly used increases. It is thereby possible to reduce the area of the capacity cell region 410 and increase a usable region generated by consolidating the delay adjustment cells.

In a layout method for a semiconductor integrated circuit according to a third embodiment of the present invention, placement of logic cells provided on an input side and an output side of delay adjustment cells is considered in addition to the layout method of the first embodiment.

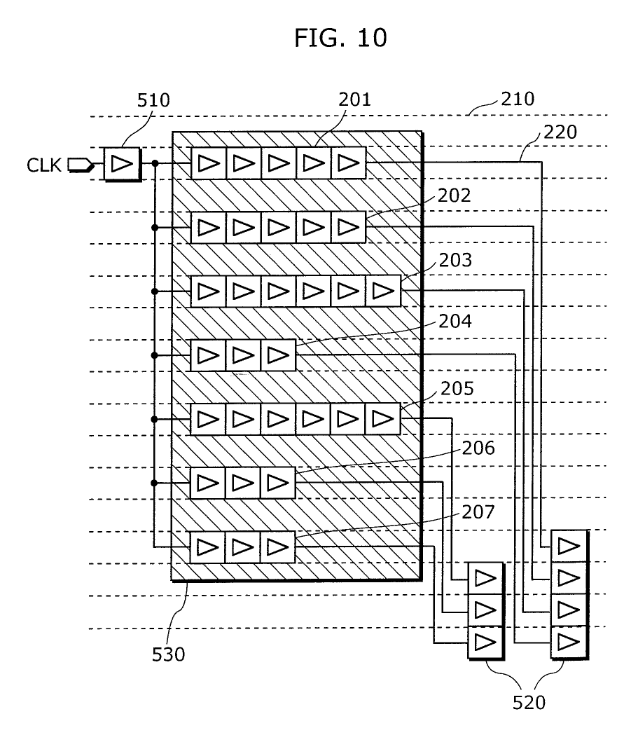

FIG. 10 is a diagram showing an example of a layout of the delay adjustment cells before consolidating the delay adjustment cells to obtain a shared delay adjustment cell (before the step S107).

The layout shown in FIG. 10 includes an input-side basic logic cell 510, output-side basic logic cells 520, a delay adjustment cell region 530 and routing 220.

The delay adjustment cell region 530 is a region where the plural delay adjustment cells 201 to 207 are placed.

The delay adjustment cells 201 and 202 are both the circuit configurations having the same kind of logic cells that generate the same delay, and generate a delay of 5 ns for instance. The delay adjustment cells 203 and 205 are both the circuit configurations having the same kind of logic cells that generate the same delay, and generate a delay of 6 ns for instance. The delay adjustment cells 204, 206 and 207 are all the circuit configurations having the same kind of logic cells that generate the same delay, and generate a delay of 3 ns for instance.

The input-side basic logic cell 510 is a logic cell of which output is connected to inputs of the plural delay adjustment cells 201 to 207.

The plural output-side basic logic cells 520 are logic cells of which inputs are connected to outputs of the plural delay adjustment cells 201 to 207 respectively.

A broken line 210 in FIG. 10 indicates a placement row which is a layout unit of the delay adjustment cells.

In the layout method for the semiconductor integrated circuit according to the third embodiment, as shown in FIG. 10, in the step S103, the input-side basic logic cell 510 and the output-side basic logic cells 520 of the plural delay adjustment cells 201 to 207 are placed on diagonally opposing sides of the delay adjustment cell region 530. For instance, as shown in FIG. 10, the input-side basic logic cell 510 is placed at the upper left side of the delay adjustment cell region 530, and the output-side basic logic cells 520 are placed at the lower right side of the delay adjustment cell region 530. The delay adjustment cells 201 to 207 are placed adjacently so that their inputs are in the same direction (left side in FIG. 10).

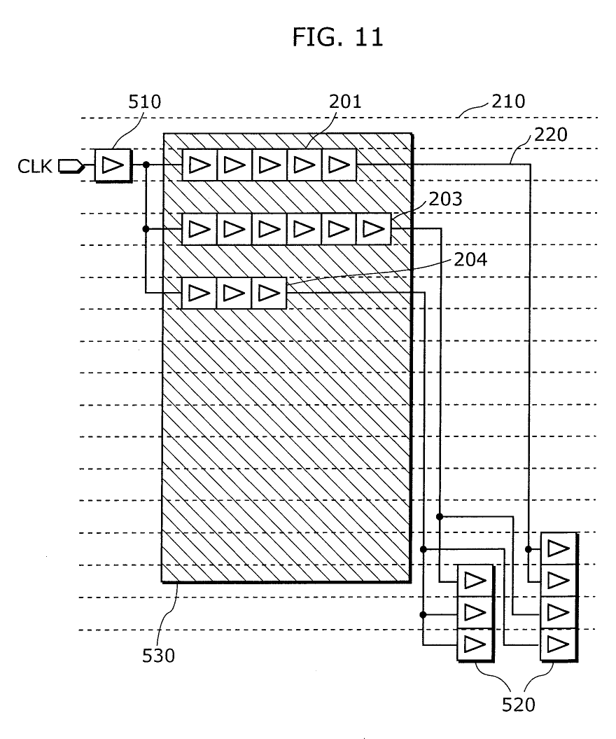

FIG. 11 is a diagram showing a layout after re-placement of the delay adjustment cells (step S109) with respect to the layout shown in FIG. 10. The same elements as in FIG. 10 are given the same symbols.

As shown in FIG. 11, the input-side basic logic cell 510 and the output-side basic logic cells 520 are placed on diagonally opposing sides of the delay adjustment cell region 530 so that a change in routing length to each of the delay adjustment cells can be reduced before and after the re-placement of the delay adjustment cells (step S109). In the case where the change in a routing configuration due to a routing modification and the re-placement is significant, delay fluctuation occurs to each clock line. Thus, a change occurs to a delay value of each clock line of which timing has been adjusted by the delay adjustment (step S106) so that there arise variations in the timing. On the other hand, as shown in FIGS. 10 and 11, in the layout method according to the third embodiment, there is no change in the routing length of each clock system from the input-side basic logic cell 510 to the output-side basic logic cells 520 before and after the re-placement of the delay adjustment cells (step S109). Therefore, it is possible to suppress the delay fluctuation in conjunction with the re-placement of the delay adjustment cells.

The placement of the input-side basic logic cell 510 and the output-side basic logic cells 520 shown in FIGS. 10 and 11 is performed when placing basic logic cells (step S103).

As described above, according to the layout method for the semiconductor integrated circuit according to the third embodiment of the present invention, the plural delay adjustment cells 201 to 207 prepared in each clock domain are placed adjacently with their input sides in the same direction when placing the basic logic cells (step S103). Furthermore, the input-side basic logic cell 510 and the output-side basic logic cells 520 of the delay adjustment cells are placed on diagonally opposing sides of the delay adjustment cell region 530. In the re-placement and re-routing by consolidating the delay adjustment cells (S108) and re-placing the delay adjustment cells (step S109), it is thereby possible to suppress a change in the overall routing length from the input-side basic logic cell 510 to the output-side basic logic cells 520 of each clock system. Therefore, it is possible to suppress fluctuation in the delay amount in conjunction with the consolidating and the re-placement of the delay adjustment cells.

In a layout method for a semiconductor integrated circuit according to a fourth embodiment of the present invention, delay adjustment cells to be consolidated to obtain a shared delay adjustment cell in a placement (floor plan) process step are predicted in addition to the layout method of the first embodiment. It is thereby possible to reduce the change in the routing length after the consolidating.

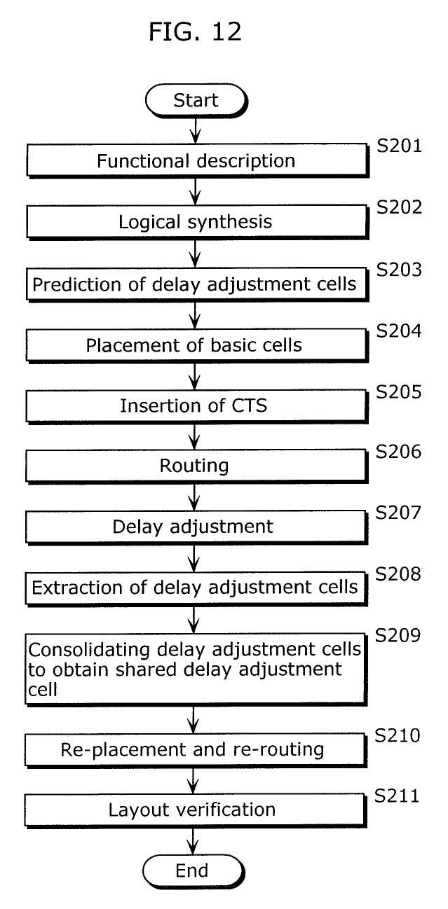

FIG. 12 is a flowchart showing a flow of processing of the layout method for the semiconductor integrated circuit according to the fourth embodiment of the present invention.

As with the first embodiment, circuit design is performed first, and functional description such as a hardware description language (HDL) or the like is performed (S201). Next, the hardware description language or the like is logically synthesized, and a netlist of a gate-level logic circuit is generated (S202).

Next, of the plural delay adjustment cells that have their delays adjusted in the delay adjustment (step S207), the delay adjustment cells to be the same kind of delay adjustment cells are predicted so as to extract the delay adjustment cells expected to have the same configuration (S203). To be more specific, the configuration of the delay adjustment cells is predicted from the delay value of the logic cells and a routing delay value predictable from placement positions of the logic cells.

Next, the basic cells including the delay adjustment cells are placed so that the plural delay adjustment cells extracted in the step S203 and predicted to be the same kind of delay adjustment cells are placed adjacently (S204).

Note that since the processing from the placement of the basic cells onward (S205 to S211) is the same as the first embodiment (corresponding to S104 to 110 of FIG. 2 respectively), a description thereof is omitted.

As described above, in the layout method for the semiconductor integrated circuit according to the fourth embodiment of the present invention, the configuration of the delay adjustment cells after the delay adjustment is predicted from the circuit configuration and placement information of each clock system and the like in advance in the step S203, and the delay adjustment cells expected to have the same configuration are placed adjacently in advance in the step S204. In the above-mentioned re-placement process steps (S208 to S210), there is a possibility that the delay fluctuation may occur due to modification of the routing. Especially, a large-scale integrated circuit has a large-scale region for placing the delay adjustment cells, and so an amount of modification in the re-placement process steps becomes large and the delay fluctuation becomes significant. On the other hand, in the layout method for the semiconductor integrated circuit according to the fourth embodiment, the configuration of the delay adjustment cells after the delay adjustment is predicted in advance, and the delay adjustment cells expected to have the same configuration are placed adjacently. Therefore, it is possible to reduce the amount of modification of placement and routing in the consolidating and the re-placement of the delay adjustment cells. It is thereby possible to suppress the delay fluctuation of the signal line of the clock system or the like in conjunction with the consolidating and the re-placement of the delay adjustment cells.

In a layout method for a semiconductor integrated circuit according to a fifth embodiment of the present invention, the number of delay adjustment cells to be consolidated to obtain one shared delay adjustment cell in consolidating the delay adjustment cells is specified in addition to the layout method of the first embodiment.

As for consolidating the delay adjustment cells in the first embodiment, all the delay adjustment cells of the same configuration are unified. When the number of the unified delay adjustment cells is large, the number of logic cells to be connected to output of a delay adjustment cell after unification becomes large. Thus, a load of the output of the delay adjustment cell after the unification becomes large, and a delay occurs. To suppress this, in the fifth embodiment, the number of the delay adjustment cells to be consolidated to obtain one shared delay adjustment cell in consolidating the delay adjustment cells is specified. It is thereby possible to suppress the delay fluctuation in conjunction with the consolidating of the delay adjustment cells.

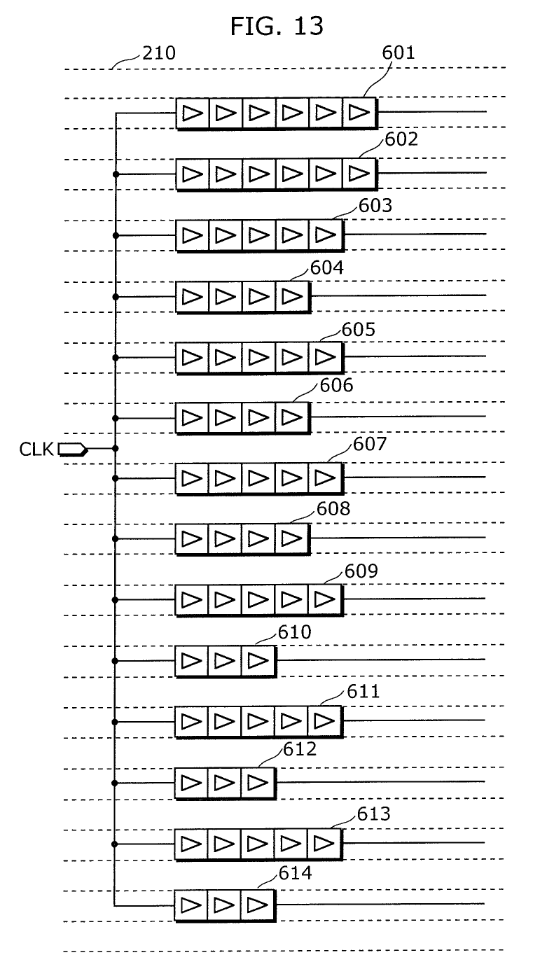

FIG. 13 is a diagram showing an example of a layout of the delay adjustment cells placed by the processing up to the step S106. The layout shown in FIG. 13 includes plural delay adjustment cells 601 to 614. Here, the delay adjustment cells 601 and 602 are the delay adjustment cells having the same delay amount; the delay adjustment cells 603, 605, 607, 609, 611 and 613 are the delay adjustment cells having the same delay amount; the delay adjustment cells 604, 606 and 608 are the delay adjustment cells having the same delay amount; and the delay adjustment cells 610, 612 and 614 are the delay adjustment cells having the same delay amount.

In the layout method according to the fifth embodiment, the same kind of delay adjustment cells extracted in the step S107 are consolidated to obtain one shared delay adjustment cell for every predetermined number or less of the delay adjustment cells in consolidating the delay adjustment cells (step S108). To be more specific, the number of the same kind of delay adjustment cells to be consolidated to obtain one shared delay adjustment cell is limited. For instance, the number of the same kind of delay adjustment cells to be consolidated to obtain one shared delay adjustment cell is limited to four or less.

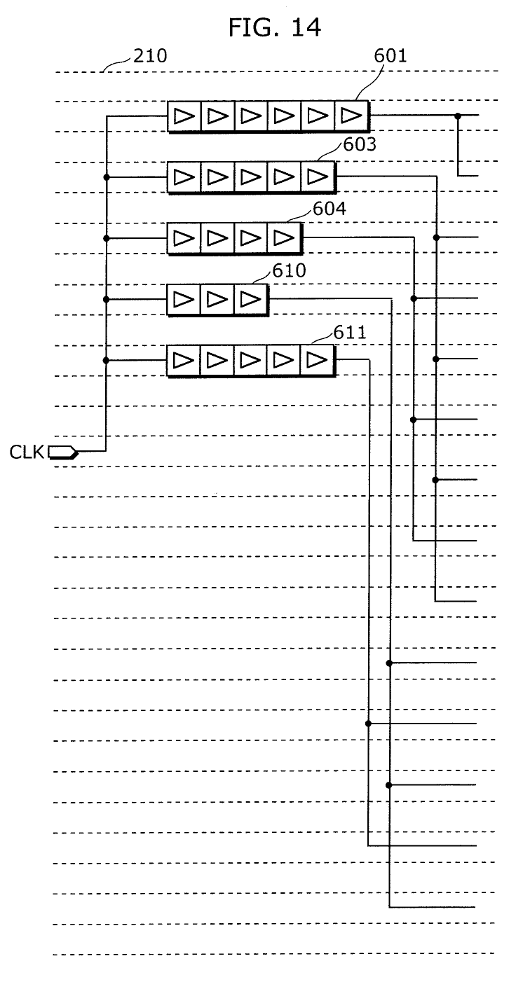

FIG. 14 is a diagram showing a layout in which the number of the same kind of delay adjustment cells to be consolidated to obtain one shared delay adjustment cell is limited to four or less, and showing the consolidated delay adjustment cells of the layout shown in FIG. 13. The same elements as in FIG. 13 are given the same symbols.

As shown in FIG. 14, the delay adjustment cells 601 and 602 of which number of the delay adjustment cells of the same delay amount is two are consolidated to obtain a shared delay adjustment cell 601. The delay adjustment cells 604, 606 and 608 of which number of the delay adjustment cells of the same delay amount is three are consolidated to obtain a shared delay adjustment cell 604. The delay adjustment cells 610, 612 and 614 of which number of the delay adjustment cells of the same delay amount is three are consolidated to obtain a shared delay adjustment cell 610. As for the delay adjustment cells 603, 605, 607, 609, 611 and 613, the number of the delay adjustment cells of the same delay amount is six which exceeds four as the limit, so that they are consolidated to obtain two shared delay adjustment cells. For instance, the delay adjustment cells 603, 605, 607 and 609 are consolidated to obtain a shared delay adjustment cell 603. The delay adjustment cells 611 and 613 are consolidated to obtain a shared delay adjustment cell 611.

As for consolidating in the case of exceeding the limit number, it is possible either to repeatedly consolidate, for every limit number, the delay adjustment cells of which number of the delay adjustment cells of the same delay amount exceeds the limit number or to equalize the number of the delay adjustment cells consolidated to obtain one shared delay adjustment cell to the extent that the number does not exceed the limit number. To be more specific, in the case where the limit number is four and the number of the delay adjustment cells of the same delay amount is six as mentioned above, it is possible either to use a method for consolidating four delay adjustment cells, the limit number, and consolidating the remaining two delay adjustment cells or to consolidate three delay adjustment cells to obtain one shared delay adjustment cell so as to equalize the number of the delay adjustment cells consolidated to obtain one shared delay adjustment cell respectively.

In the above description, the limit number of the delay adjustment cells consolidated to obtain one shared delay adjustment cell is four. However, the limit number may be set to an arbitrary number.

As described above, in the layout method for the semiconductor integrated circuit according to the fifth embodiment of the present invention, the number of the delay adjustment cells of the same configuration to be consolidated to obtain one shared delay adjustment cell is limited in consolidating the delay adjustment cells. It is thereby possible to limit the number of outputs (fan-outs) of output cells in a final stage of the delay adjustment cells which become a cause of a delay and suppress the delay fluctuation.

In a layout method for a semiconductor integrated circuit according to a sixth embodiment of the present invention, consolidating and re-placing are performed with respect to each of divided regions in consolidating and re-placing in addition to the first embodiment.

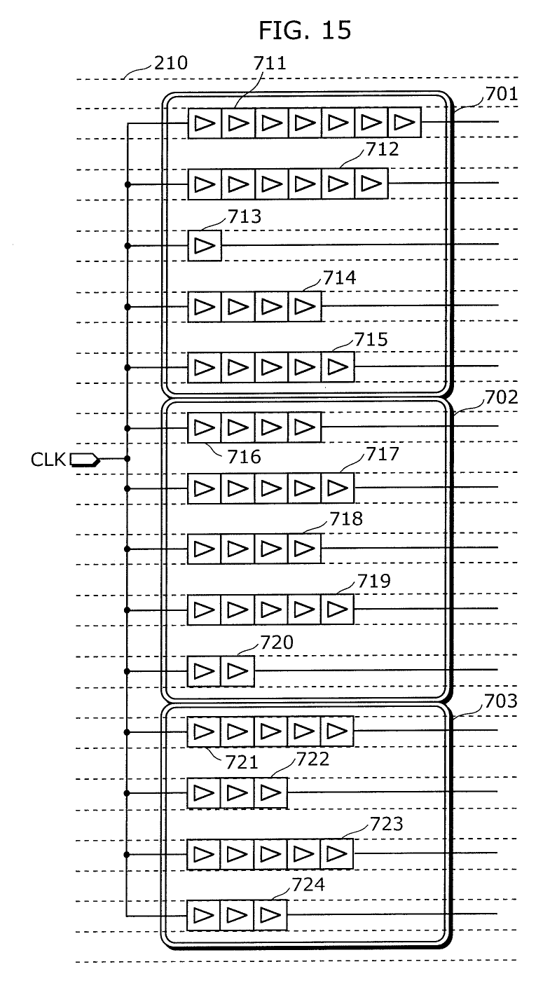

FIG. 15 is a diagram showing an example of a layout of delay adjustment cells after a delay adjustment (step S106). The layout shown in FIG. 15 includes plural delay adjustment cells 711 to 724.

In the layout method for the semiconductor integrated circuit according to the sixth embodiment, the region where the plural delay adjustment cells were placed in the step S103 is divided into plural re-placement target regions. In the step S107, the same kind of delay adjustment cells are extracted respectively from among the plural delay adjustment cells included in the re-placement target regions, and, in the step S108, the extracted same kind of delay adjustment cells are consolidated to obtain one shared delay adjustment cell for every re-placement target region. For instance, as shown in FIG. 15, the delay adjustment cells 711 to 724 are divided to form three re-placement target regions 701 to 703. Consolidating and re-placing are performed to each of the divided re-placement target regions 701 to 703.

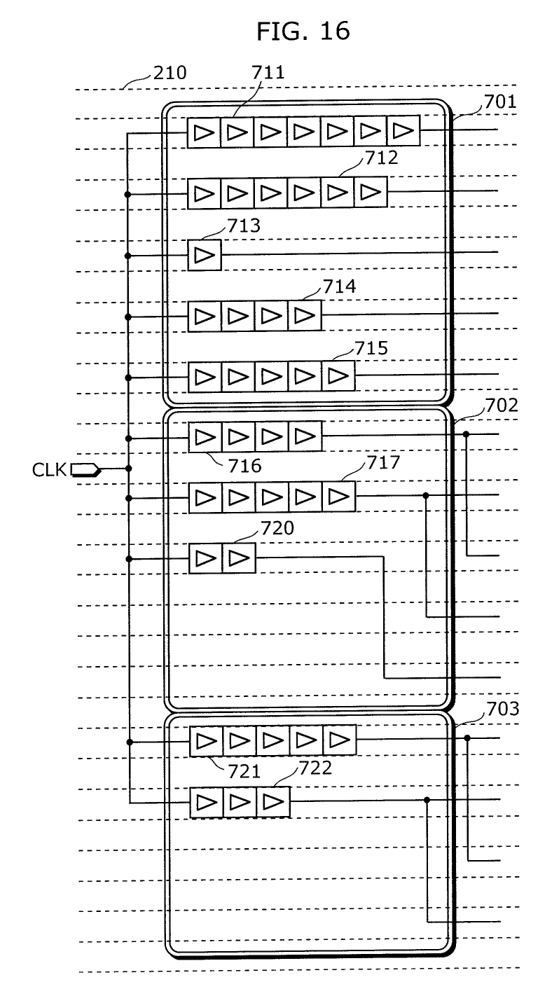

FIG. 16 is a diagram showing a layout in which the delay adjustment cells shown in FIG. 15 are consolidated and re-placed by using the layout method for the semiconductor integrated circuit according to the sixth embodiment. The same elements as in FIG. 15 are given the same symbols.

In FIG. 15, the re-placement target region 701 includes the delay adjustment cells 711 to 715. In the re-placement target region 701, there is no delay adjustment cell having the same delay amount, and so consolidating and re-placing are not performed.

In FIG. 15, the re-placement target region 702 includes the delay adjustment cells 716 to 720. In the re-placement target region 702, the delay adjustment cells 716 and 718 have the same delay amounts, and delay adjustment cells 717 and 719 have the same delay amounts. Therefore, as shown in FIG. 16, the delay adjustment cells 716 and 718 are consolidated to obtain a shared delay adjustment cell 716, and the shared delay adjustment cell 716 is re-placed. The delay adjustment cells 717 and 719 are consolidated to obtain a shared delay adjustment cell 717, and the shared delay adjustment cell 717 is re-placed.

In FIG. 15, the re-placement target region 703 includes the delay adjustment cells 721 to 724. In the re-placement target region 703, the delay adjustment cells 721 and 723 have the same delay amounts, and delay adjustment cells 722 and 724 have the same delay amounts. Therefore, as shown in FIG. 16, the delay adjustment cells 721 and 723 are consolidated to obtain a shared delay adjustment cell 721, and the shared delay adjustment cell 721 is re-placed. The delay adjustment cells 722 and 724 are consolidated to obtain a shared delay adjustment cell 722, and the shared delay adjustment cell 722 is re-placed.

Moreover, as for a method for setting up regions for performing consolidating and re-placing, it is possible to use the method for setting them up by layout area, the method for setting them up by the number of the delay adjustment cells, or the like. For instance, five delay adjustment cells at the maximum are set up as one re-placement target region as shown in FIG. 15.

As described above, in the layout method for the semiconductor integrated circuit according to the sixth embodiment of the present invention, the region of the layout having the delay adjustment cells 711 to 724 placed therein is divided into the plural re-placement target regions 701 to 703, and the delay adjustment cells are consolidated and re-placed for each of the divided re-placement target regions 701 to 703. It is thereby possible to suppress extension of the routing after the re-placement and reduce influence of the delay fluctuation.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to a layout method for a semiconductor integrated circuit, and particularly to a layout method for a semiconductor integrated circuit including a large-scale logic circuit which performs automatic placement and routing.

What is claimed is:

1. A layout method for a semiconductor integrated circuit including a plurality of delay adjustment cells each of which adjusts a delay amount of a signal line, said layout method comprising:
placing the plurality of delay adjustment cells;
adjusting delay amounts of the plurality of delay adjustment cells placed in said placing;
extracting delay adjustment cells of a same kind from among the plurality of delay adjustment cells having the delay amounts adjusted in said adjusting; and
consolidating the delay adjustment cells of the same kind extracted in said extracting, to obtain a shared delay adjustment cell.

2. The layout method for a semiconductor integrated circuit according to claim 1, further comprising
re-placing the plurality of delay adjustment cells including the shared delay adjustment cell obtained in said consolidating, so as to reduce area of a region where the plurality of delay adjustment cells are placed.

3. The layout method for a semiconductor integrated circuit according to claim 2,
wherein said re-placing includes aligning and re-placing the plurality of delay adjustment cells including the shared delay adjustment cell obtained in said consolidating, in an order depending on a size of the area of the delay adjustment cells.

4. The layout method for a semiconductor integrated circuit according to claim 1,
wherein said placing includes placing an input-side logic cell and an output-side logic cell of the plurality of delay adjustment cells, so that the input-side logic cell and the output-side logic cell are respectively arranged on diagonally opposing sides of a region where the plurality of delay adjustment cells are placed.

5. The layout method for a semiconductor integrated circuit according to claim 1, further comprising
predicting the delay adjustment cells of the same kind from among the plurality of delay adjustment cells,
wherein said placing includes adjacently placing the delay adjustment cells of the same kind predicted in said predicting.

6. The layout method for a semiconductor integrated circuit according to claim 1,
wherein said consolidating includes consolidating the delay adjustment cells of the same kind extracted in said extracting, to obtain one shared delay adjustment cell for every predetermined number or less of the delay adjustment cells.

7. The layout method for a semiconductor integrated circuit according to claim 1, further comprising:
dividing a region where the plurality of delay adjustment cells are placed in said placing into a plurality of re-placement target regions, and
wherein said extracting includes extracting the delay adjustment cells of the same kind from among the plurality of delay adjustment cells included in each of the re-placement target regions; and
said consolidating includes consolidating the delay adjustment cells of the same kind extracted in said extracting to obtain the shared delay adjustment cell, for each of the re-placement target regions.

8. A program which causes a computer to execute a layout method for a semiconductor integrated circuit including a plurality of delay adjustment cells each of which adjusts a delay amount of a signal line,
the method includes:
placing the plurality of delay adjustment cells;
adjusting delay amounts of the plurality of delay adjustment cells placed in said placing;
extracting delay adjustment cells of a same kind from among the plurality of delay adjustment cells having the delay amounts adjusted in said adjusting; and
consolidating the delay adjustment cells of the same kind extracted in said extracting, to obtain a shared delay adjustment cell.

9. A semiconductor integrated circuit comprising:
a delay adjustment cell having an input connected to a clock terminal and which imparts a predetermined delay to an inputted signal and output the signal;
a plurality of selectors each of which selects one of the signal outputted by the delay adjustment cell and a signal from a test terminal, and outputs the signal; and
a plurality of flip-flops each of which has a clock input terminal to which the signal outputted by one of said plurality of selectors is inputted.
